(19) United States
(12) Patent Application Publication
(10) Pub. No.: US 2021/0366731 A1
(43) Pub. Date: Nov. 25, 2021

(54) MASK, USAGE METHOD THEREOF, AND MANUFACTURING METHOD OF ENCAPSULATION LAYER

(71) Applicant: WUHAN CHINA STAR OPTOELECTRONICS SEMICONDUCTOR DISPLAY TECHNOLOGY CO., LTD., Wuhan, Hubei (CN)

(72) Inventors: Yike WANG, Wuhan, Hubei (CN); Jianguo GONG, Wuhan, Hubei (CN)

(21) Appl. No.: 16/962,241

(22) PCT Filed: Jun. 19, 2020
(86) PCT No.: PCT/CN2020/097047

§ 371 Date: Jul. 15, 2020

(30) Foreign Application Priority Data
May 19, 2020 (CN) 202010424943.2

(51) Int. Cl. H01L 21/56; H01L 23/29; H01L 21/04; C23C 14/04

(52) U.S. Cl. CPC H01L 21/56; C23C 14/042; H01L 21/0465; H01L 23/29

(57) ABSTRACT

The invention relates to a mask, a usage method thereof, and a manufacturing method of an encapsulation layer. A sum of gravity on a first area and external stress is less than gravity on a second area of the mask, and the sum of the gravity on the first area and external stress is greater than gravity on a third area. The first area of the mask has a lesser deformation amount, or almost no deformation, thereby a bonding area between the first area of the mask and a glass substrate is increased and a width of a deformation area at an edge of the mask is reduced.

The present application claims priority of a Chinese patent application filed with the National Intellectual Property Administration on May 19, 2020, application No. 202010424943.2, titled “Mask, usage method thereof, and manufacturing method of encapsulation layer”, which is incorporated by reference in the present application in its entirety.

### FIELD OF INVENTION

The invention relates to the field of display technology, in particular to a mask, a usage method thereof, and a method of manufacturing an encapsulation layer.

### BACKGROUND OF INVENTION

Display devices can convert data in a computer into various words, digits, symbols, or intuitive images and display them. In addition, we can use a keyboard or other input tools to input commands or data into a computer, and with help of system's hardware and software, display content can be added, deleted, and changed at any time. Display devices are classified into types such as plasma, liquid crystal, light-emitting diode, and cathode ray tube according to display elements they use.

Organic light-emitting display devices (organic light-emitting diode, or OLED) are also referred to as organic electroluminescent display devices and organic light-emitting semiconductors. A working principle of OLEDs is: when electric power supplied reaches an appropriate voltage, an electron hole and a cathode electric charge combine in a light-emitting layer. Under action of Coulomb force, they combine with a certain probability to form an exciton (electron-hole pair) in an excited state, and the excited state is unstable in a usual environment. Excitons in the excited state combine and transfer energy to luminescent materials, making them transit from a ground-state energy level to that of the excited state. Excited-state energy generates photons through a radiation relaxation process to release light energy, emit light, and produce three primary colors of red, green, and blue (RGB) according to different formulas and thereby forming basic colors.

OLED has advantages of low voltage demand, high power-saving efficiency, fast response times, lightness, thinness, simple structure, low cost, wide viewing angles, almost infinitely high contrast ratio, low power consumption, and extremely fast response speed. Thus, it has become one of the most important display technologies.

### Technical Problem

Film layers in OLED structure are very sensitive to oxygen and moisture, and they are extremely prone to failure. Therefore, thin-film package technology is used in the OLED structure to block water and oxygen to prevent device damage. In the thin-film package technology, a mask is often used to form a film layer.

As shown in FIG. 1, due to a thickness of current mask being uniform, gravity on the entire mask everywhere is the same. Under an effect of stress at a center position, two ends of the mask will warp, forming a V-shaped deformation. As a result, a gap between the mask 100 and a glass substrate 200 below an edge position of a coating effective area 101 is greater. The gap is formed between an edge of the mask and the glass substrate, and materials enter the gap during coating, which causes a shadow phenomenon and uneven film thickness, thereby affecting package performance of an encapsulation layer. Therefore, it is necessary to find a new type mask to solve the above problems.

### SUMMARY OF INVENTION

The object of the present invention is to provide a mask, a method of manufacturing an encapsulation layer, and a display device. It can solve the problems that the warpage of the mask causes a gap between the mask and the glass substrate at an edge of coating effective area to be too great, resulting in a shadow phenomenon and uneven film thickness, and affecting package performance.

In order to solve the above problems, the present invention provides a mask, which includes: a first area; a second area surrounding the first area; and a third area surrounding the second area; wherein a thickness of the second area is greater than a thickness of the first area, and the thickness of the first area is greater than a thickness of the third area.

Further, a ratio of the thickness of the first area to the thickness of the second area is between 0.5 and 0.7.

Further, a ratio of the thickness of the third area to the thickness of the second area is between 0.3 and 0.4.

Further, the second area is ring-shaped.

In order to solve the above problems, the present invention provides a method of using a mask, including following steps: providing a mask according to the present invention on a substrate, depositing an inorganic layer on the substrate and the mask, and removing the mask.

Further, the substrate includes a glass base or an organic layer.

In order to solve the above problems, the present invention provides a method of manufacturing an encapsulation layer, including following steps: forming a first inorganic layer on an upper surface of a glass substrate. Specifically includes following steps: providing the mask according to the present invention on a substrate, depositing an inorganic layer on the substrate and the mask, and removing the mask.

Further, the method of manufacturing the encapsulation layer includes: forming an organic layer on an upper surface of the first inorganic layer.

Further, the method of manufacturing the encapsulation layer further includes: forming a second inorganic layer on an upper surface of the organic layer.

Further, steps of forming the second inorganic layer specifically include following steps: providing the mask according to the present invention on the organic layer, depositing a second inorganic layer on the organic layer and the mask, and removing the mask.

### Beneficial Effect

The invention relates to a mask, a usage method thereof, and a manufacturing method of an encapsulation layer. The mask is defined as a first area, a second area, and a third area, and a thickness of the second area is made greater than a thickness of the first area; the thickness of the first area is made greater than a thickness of the third area. By changing the thicknesses of the first area, the second area, and the third area of the mask, the gravity on each corresponding area of the mask is changed. As a result, a sum of the gravity on the first area and external stress is less than the gravity on the second area of the mask, and a sum of the gravity on the first area and external stress is greater than the gravity on the third area so that the mask in the second area bears the greatest force. The first area of the mask has a lesser deformation amount, or almost no deformation, thereby the bonding area between the first area of the mask and the glass substrate is increased and the width of the deformation area at the edge of the mask is reduced. The second area and the third area of the mask are warped upward, and the deformation amount of the third area is greater than that of the second area, thereby the distance between the deformation area at the edge of the mask and the glass substrate is reduced. Since the width of the deformation area at the edge of the mask is reduced, the distance between the deformation area and the glass substrate is reduced. Therefore, a gap between the edge of the mask and the glass substrate becomes smaller, less material enters the gap when coating so that the shadow area generated during coating is reduced, the uniformity of the film thickness is improved, and the reliability of the encapsulation layer is enhanced.

### DESCRIPTION OF DRAWINGS

In order to more clearly illustrate the technical solutions in the embodiments of the present invention, the following figures described in the embodiments will be briefly introduced. It is obvious that the drawings described below are merely some embodiments of the present invention, other drawings can also be obtained by the person ordinary skilled in the field based on these drawings without doing any creative activity.

FIG. 1 is a schematic diagram of bonding of a mask and a glass substrate under action of gravity in the prior art.

FIG. 2 is a schematic plan view of a mask of the present invention.

FIG. 3 is an enlarged view of a first area of the mask of the present invention.

FIG. 4 is a schematic view of the mask of the present invention attached to a glass substrate under action of gravity.

FIG. 5 is a flowchart of a method for manufacturing an encapsulation layer of the present invention.

FIG. 6 is a schematic structural view of manufacturing an encapsulation layer by vapor deposition method.

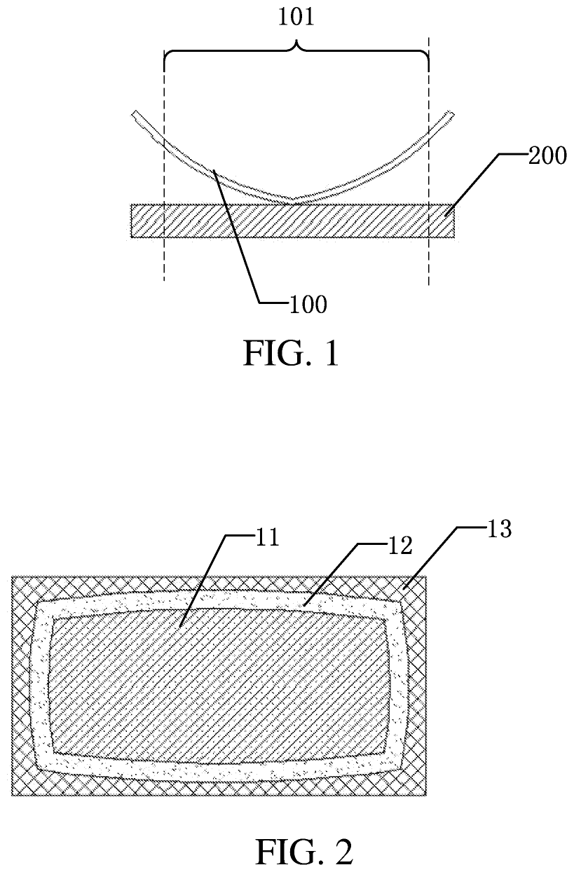

### REFERENCE NUMERALS

100 prior art mask, 200 glass substrate, 101 effective area, 1 mask of the present invention, 2 glass substrate, 3 carrier, 11 first area, 12 second area, 13 third area, 111 effective area

### DETAILED DESCRIPTION OF PREFERRED EMBODIMENTS

The following describes the preferred embodiments of the present invention in detail with reference to the accompanying drawings of the specification to fully introduce the technical content of the present invention to those skilled in the art, so as to prove that the present invention can be implemented. The technical content disclosed in the present invention is made clearer, and it is easier for those skilled in the art to understand how to implement the present invention. However, the present invention can be achieved by various forms of embodiments. The protection scope of the present invention is not limited to the embodiments mentioned in this article. The description of the embodiments below is not intended to limit the scope of the present invention.

Directional terminology mentioned in the application, such as “above”, “under”, “front”, “back”, “left”, “right”, “inside”, “outside”, “side”, etc., are only refer to the directions of the accompanying drawings. The directional terminology used herein is used to explain the present invention, rather than to limit the protection scope of the present invention.

In the drawings, components with the same structure are denoted by the same numerals, and components with similar structures or functions are denoted by similar numerals. In addition, for ease of understanding and description, the size and thickness of each component shown in the drawings are arbitrarily shown, and the present invention does not limit the size and thickness of each component.

When one component is described as “on” another component, the component can be directly placed on another component. There can also be an intermediate component, the component is placed on the intermediate component, and the intermediate component is placed on another component. When a component is described as “installed to” or “connected to” another component, it can be understood as “installed to” or “connecting to” directly, or one component is “installed to” or “connected” to another component through an intermediate component.

### EMBODIMENT

As shown in FIG. 2, this embodiment provides a mask 1 including: a first area 11, a second area 12, and a third area 13.

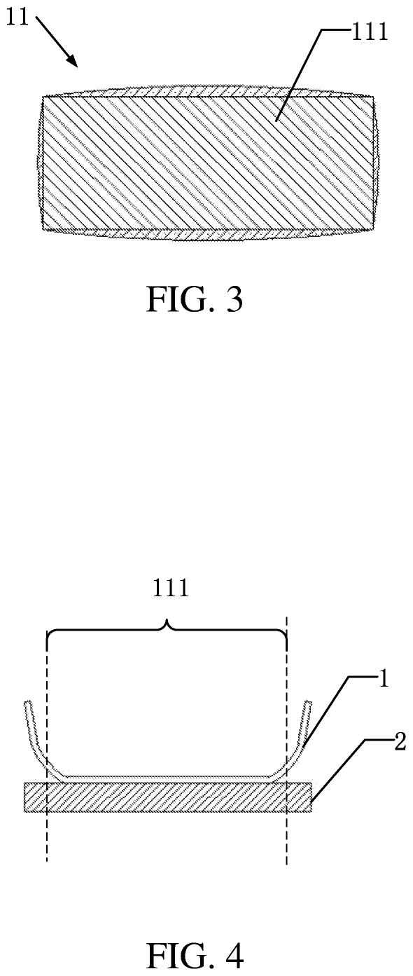

As shown in FIGS. 2 and 3, the first area 11 includes an effective area 111. The effective area means a coating safety area.

As shown in FIG. 2, the second area 12 surrounds the first area 11, wherein the second area 12 has a ring shape.

As shown in FIG. 2, the third area 13 surrounds the second area 12.

As shown in FIGS. 2 and 4, a thickness of the second area 12 is greater than a thickness of the first area 11, and the thickness of the first area 11 is greater than a thickness of the third area 13.

A ratio of the thickness of the first area 11 to the thickness of the second area 12 is between 0.5 and 0.7. In this embodiment, a ratio of the thickness of the first area 11 to the thickness of the second area 12 is preferably 0.6.

A ratio of the thickness of the third area to the thickness of the second area is between 0.3 and 0.4. In this embodiment, a ratio of the thickness of the third area 13 to the thickness of the second area 12 is preferably 0.4.

As described above, by changing thicknesses of the first area 11, the second area 12, and the third area 13 of the mask 1, the gravity on each corresponding area of the mask 1 is changed. As a result, a sum of the gravity on the first area 11 and external stress is less than the gravity on the second area 12 of the mask 1, and a sum of the gravity on the first area 11 and external stress is greater than the gravity on the third area 13 so that the mask in the second area 12 bears the greatest force. The first area 11 of the mask 1 has a lesser deformation amount, or almost no deformation, thereby the bonding area between the first area 11 of the mask 1 and the glass substrate 2 is increased and the width of the deformation area at the edge of the mask 1 is reduced.

The second area 12 and the third area 13 of the mask are warped upward, and the deformation amount of the third area 13 is greater than that of the second area 12, thereby the distance between the deformation area at the edge of the mask 1 and the glass substrate is reduced.

Since the width of the deformation area at the edge of the mask 1 is reduced, the distance between the deformation area and the glass substrate is reduced. Therefore, a gap between the edge of the mask 1 and the glass substrate becomes smaller, less material enters the gap when coating so that the shadow area generated during coating is reduced, the uniformity of the film thickness is improved, and the reliability of the encapsulation layer is enhanced.

This embodiment also provides a method of using a mask 1, including following steps: providing the mask 1 on a substrate; depositing an inorganic layer on the substrate and the mask; and removing the mask 1.

The substrate includes a glass base or an organic layer.

Since the thicknesses of the first area 11, the second area 12, and the third area 13 of mask 1 are changed, the gravity on each corresponding area of the mask changes. As a result, a sum of the gravity on the first area 11 and external stress is less than the gravity on the second area of the mask, and a sum of the gravity on the first area 11 and external stress is greater than the gravity on the third area 13 so that the mask 1 in the second area 12 bears the greatest force. As a result, the first area 11 of the mask 1 has a lesser deformation amount, or almost no deformation, thereby the bonding area between the first area 11 of the mask 1 and the glass substrate 2 is increased and the width of the deformation area at the edge of the mask 1 is reduced.

The second area 12 and the third area 13 of the mask are warped upward, and the deformation amount of the third area 13 is greater than that of the second area 12, thereby the distance between the deformation area at the edge of the mask 1 and the glass substrate is reduced.

Since the width of the deformation area at the edge of the mask 1 is reduced, the distance between the deformation area and the glass substrate is reduced. Therefore, a gap between the edge of the mask 1 and the glass substrate becomes smaller, less material enters the gap when coating so that the shadow area generated during coating is reduced, the uniformity of the film thickness is improved, and the reliability of the encapsulation layer is enhanced.

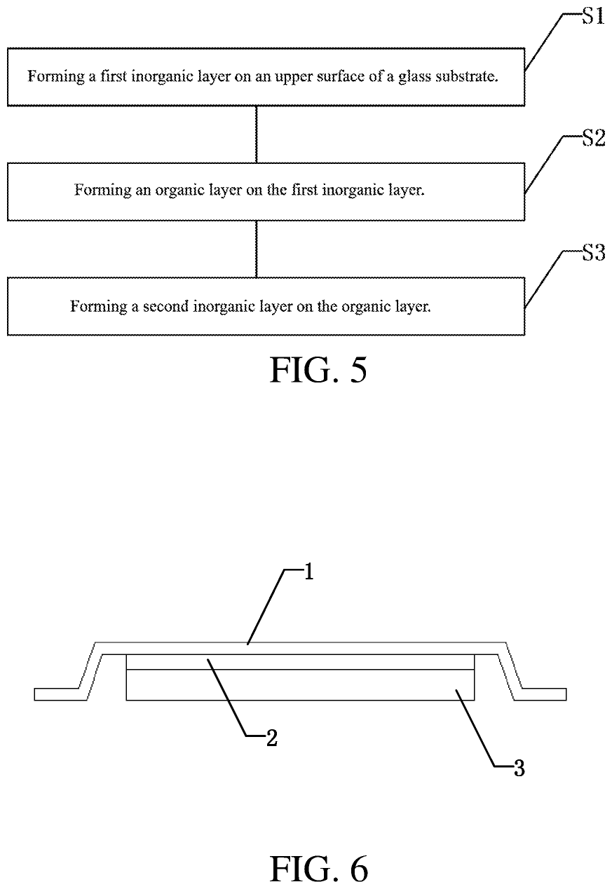

As shown in FIG. 5, this embodiment also provides a method of manufacturing an encapsulation layer, including: S1, forming a first inorganic layer on an upper surface of a glass substrate 2; S2, forming an organic layer on the first inorganic layer; and S3, forming a second inorganic layer on the organic layer.

As shown in FIG. 6, wherein S1 includes: providing a carrier 3, providing a glass substrate 2 on the carrier 3, providing a mask 1 on the glass substrate 2, depositing a first inorganic layer on the glass substrate 2 and the mask 1, and removing the mask 1.

Since the thicknesses of the first area 11, the second area 12, and the third area 13 of the mask 1 are changed, the gravity on each corresponding area of the mask changes. As a result, a sum of the gravity on the first area 11 and external stress is less than the gravity on the second area 12 of the mask, and a sum of the gravity on the first area 11 and external stress is greater than the gravity on the third area 13 so that the mask 1 in the second area 12 bears the greatest force. The first area 11 of the mask 1 has a lesser deformation amount, or almost no deformation, thereby the bonding area between the first area 11 of the mask 1 and the glass substrate 2 is increased and the width of the deformation area at the edge of the mask 1 is reduced.

The second area 12 and the third area 13 of the mask are warped upward, and the deformation amount of the third area 13 is greater than that of the second area 12, thereby the distance between the deformation area at the edge of the mask 1 and the glass substrate is reduced.

Since the width of the deformation area at the edge of the mask 1 is reduced, the distance between the deformation area and the glass substrate is reduced. Therefore, a gap between the edge of the mask 1 and the glass substrate becomes smaller, less material enters the gap when coating so that the shadow area generated during coating is reduced. This embodiment uses the mask 1 to form a first inorganic layer, which can improve the uniformity of film thickness of the first inorganic layer and finally improve the encapsulation performance of the encapsulation layer.

In S2, an inkjet printing technology is used to form an organic layer on the first inorganic layer. In S3, a second inorganic layer is formed on the organic layer by a vapor deposition method. S3 specifically includes the following steps: providing the mask 1 on the organic layer, depositing a second inorganic layer on the organic layer and the mask 1, and removing the mask 1.

Since the thicknesses of the first area 11, the second area 12, and the third area 13 of the mask 1 are changed, the gravity on each corresponding area of the mask changes. As a result, a sum of the gravity on the first area 11 and external stress is less than the gravity on the second area 12 of the mask 1, and a sum of the gravity on the first area 11 and external stress is greater than the gravity on the third area 13 so that the mask 1 in the second area 12 bears the greatest force. The first area 11 of the mask 1 has a lesser deformation amount, or almost no deformation, thereby the bonding area between the first area 11 of the mask 1 and the glass substrate 2 is increased and the width of the deformation area at the edge of the mask 1 is reduced.

The second area 12 and the third area 13 of the mask are warped upward, and the deformation amount of the third area 13 is greater than that of the second area 12, thereby the distance between the deformation area at the edge of the mask 1 and the glass substrate is reduced.

Since the width of the deformation area at the edge of the mask 1 is reduced, the distance between the deformation area and the glass substrate is reduced. Therefore, a gap between the edge of the mask 1 and the glass substrate becomes smaller, less material enters the gap when coating so that the shadow area generated during coating is reduced. This embodiment uses the mask 1 to form a second inorganic layer, which can improve the uniformity of film thickness of the second inorganic layer and finally improve the encapsulation performance of the encapsulation layer.

A mask, a usage method thereof, and a manufacturing method of an encapsulation layer provided by this application have been described in detail above. This article uses specific examples to explain the principles and implementation of this application. The descriptions of the above embodiments are only used to help understand the technical solutions and core ideas of the present application. Those of ordinary skill in the art should understand that they can modify the technical solutions described in the embodiments, or equivalently substitute some of the technical features. However, these modifications or substitutions do not deviate the essence of the corresponding technical solutions from the scope of the technical solutions of the present application.

What is claimed is:

1. A mask, comprising:
a first area;
a second area surrounding the first area; and
a third area surrounding the second area;
wherein, a thickness of the second area is greater than a thickness of the first area, and the thickness of the first area is greater than a thickness of the third area.

2. The mask according to claim 1, wherein a ratio of the thickness of the first area to the thickness of the second area is between 0.5 and 0.7.

3. The mask according to claim 1, wherein a ratio of the thickness of the third area to the thickness of the second area is between 0.3 and 0.4.

4. The mask according to claim 1, wherein the second area is ring-shaped.

5. A usage method of a mask, comprising steps of:
providing the mask of claim 1 on a substrate;
depositing an inorganic layer on the substrate and the mask; and
removing the mask;
wherein the mask comprises:
the first area;
the second area surrounding the first area; and
the third area surrounding the second area;
wherein the thickness of the second area is greater than the thickness of the first area, and the thickness of the first area is greater than the thickness of the third area.

6. The method of using the mask according to claim 5, wherein a ratio of the thickness of the first area to the thickness of the second area is between 0.5 and 0.7.

7. The method of using the mask according to claim 5, wherein a ratio of the thickness of the third area to the thickness of the second area is between 0.3 and 0.4.

8. The method of using the mask according to claim 5, wherein the second area is ring-shaped.

9. The method of using the mask according to claim 5, wherein the substrate comprises a glass base or an organic layer.

10. A method of manufacturing an encapsulation layer, comprising forming a first inorganic layer on an upper surface of a glass substrate, wherein the method specifically comprises steps of:
providing the mask of claim 1 on a substrate; and
depositing an inorganic layer on the substrate and the mask; and
removing the mask;
wherein the mask comprises:
the first area;
the second area surrounding the first area; and
the third area surrounding the second area;
wherein the thickness of the second area is greater than the thickness of the first area, and the thickness of the first area is greater than the thickness of the third area.

11. The method of manufacturing the encapsulation layer according to claim 10, wherein a ratio of the thickness of the first area to the thickness of the second area is between 0.5 and 0.7.

12. The method of manufacturing the encapsulation layer according to claim 10, wherein a ratio of the thickness of the third area to the thickness of the second area is between 0.3 and 0.4.

13. The method of manufacturing the encapsulation layer according to claim 10, wherein the second area is ring-shaped.

14. The method of manufacturing the encapsulation layer according to claim 10, further comprising:
forming an organic layer on an upper surface of the first inorganic layer.

15. The method of manufacturing the encapsulation layer according to claim 14, further comprising:
forming a second inorganic layer on an upper surface of the organic layer.

16. The method of manufacturing the encapsulation layer according to claim 15, wherein steps of forming the second inorganic layer specifically comprises:
providing the mask of claim 1 on the organic layer;
depositing the second inorganic layer on the organic layer and the mask; and
removing the mask;
wherein the mask comprises:
the first area;
the second area surrounding the first area; and
the third area surrounding the second area;
wherein the thickness of the second area is greater than the thickness of the first area, and the thickness of the first area is greater than the thickness of the third area.

17. The method of manufacturing the encapsulation layer according to claim 16, wherein a ratio of the thickness of the first area to the thickness of the second area is between 0.5 and 0.7.

18. The method of manufacturing the encapsulation layer according to claim 16, wherein a ratio of the thickness of the third area to the thickness of the second area is between 0.3 and 0.4.

19. The method of manufacturing the encapsulation layer according to claim 16, wherein the second area is ring-shaped.
